(19) United States
(12) Patent Application Publication
(10) Pub. No.: US 2006/0145278 A1
(43) Pub. Date: Jul. 6, 2006

(54) CMOS image sensor and method for manufacturing the same

(75) Inventor: Chang Eun Lee, Mapo-gu (KR)

Correspondence Address: MCKENNA LONG & ALDRIDGE LLP, 1900 K STREET, NW, WASHINGTON, DC, 20006, US

(73) Assignee: DONGBUANAM SEMICONDUCTOR INC., Kangnam-Ku (KR)

(21) Appl. No.: 11/319,496

(22) Filed: Dec. 29, 2005

(30) Foreign Application Priority Data
Dec. 30, 2004 (KR) 10-2004-0116426

(51) Int. Cl. H01L 31/0232

(52) U.S. Cl. 257/432

(57) ABSTRACT

A CMOS image sensor includes a plurality of photodiodes in a semiconductor substrate; an insulating interlayer on the semiconductor substrate including the plurality of photodiodes; a metal line in the insulating interlayer; a passivation layer on the insulating interlayer; an adhesive layer on the passivation layer; and a plurality of micro-lenses on the adhesive layer.

### CROSS-REFERENCE TO RELATED APPLICATION

This application claims the benefit of Korean Patent Application No. 10-2004-0116426, filed on Dec. 30, 2004, which is hereby incorporated by reference for all purposes as if fully set forth herein.

### BACKGROUND OF THE INVENTION

1. Field of the Invention

The present invention relates to a CMOS image sensor and a method for manufacturing the same, and more particularly, to a CMOS image sensor and a method for manufacturing the same to prevent a lifting effect of a microlens.

2. Discussion of the Related Art

Generally, an image sensor is a semiconductor device for converting an optical image to an electric signal. The image sensor is classified as a charge coupled device (CCD) or a complementary metal oxide silicon (CMOS) image sensor.

For a CCD, metal-oxide-silicon MOS capacitors are adjacently positioned from one another, and electric carriers are stored in and transferred from the MOS capacitors. For a CMOS image sensor, the number of MOS transistors corresponds to the number of pixels and uses a control circuit and a signal processing circuit as peripheral circuits, whereby output signals are sequentially output with the MOS transistors in a switching method.

The CMOS image sensor changes light signals to electric signals. The CMOS image sensor is comprised of signal processing chips which include photodiodes. Each of the signal processing chips is provided with an amplifier, an analog-digital converter, an internal voltage generator, a timing generator, and digital logic. The CMOS image sensor has advantages in that it can decrease space, power, and cost.

Also, the CCD is fabricated by a high priced, specialized process, but the CMOS image sensor is fabricated by mass production by an inexpensive silicon wafer etching process. In addition, the CMOS image sensor is highly integrated.

As a result, the CMOS image sensor is applied to various products, for example, a digital camera, a smart phone, a PDA, a notebook computer, a security camera, a bar-code reader, a toy, etc.

To enhance the photo-sensitivity of the CMOS image sensor, it is necessary to improve the fill factor. The fill factor is the area of the photodiode relative the entire area of the CMOS image sensor. However, the ability to increase the fill factor is limited by the physical presence of a logic circuit for signal processing.

To improve photosensitivity, incident light in portions other than the photodiode can be concentrated into the photodiode. A microlens pattern may be provided to concentrate the incident light into the photodiode.

The microlens pattern is generally formed on a nitride layer which functions as a passivation layer. The nitride layer has a poor adherence to photoresist, which is the main element of the microlens pattern. As a result, it may cause a problem, such as a lift effect of the microlens pattern. Also, if a metal line inside the CMOS image sensor is positioned on the path of light, it generates a diffused reflection of light, thereby deteriorating the picture quality of the CMOS image sensor.

Hereinafter, a method for manufacturing a CMOS image sensor according to the related art will be described with reference to the accompanying drawings.

FIG. 1 is a cross sectional view of a CMOS image sensor according to the related art.

As shown in FIG. 1, a first epitaxial layer (not shown) is grown on a semiconductor substrate 10, and a red photodiode 11 is formed on the semiconductor substrate 10. Then, a second epitaxial layer 12 is grown on the first epitaxial layer, including the red photodiode 11, and a green photodiode 13 is formed in the second epitaxial layer 12. Then, a third epitaxial layer 14 is grown on the second epitaxial layer 12, including the green photodiode 13. A trench is then formed in the third epitaxial layer 14 for isolation between the green photodiode 15 and a field, and then the trench is filled with an insulating material, thereby forming an shallow trench isolation (STI) 16.

Thereafter, an insulating interlayer 17 is deposited on the third epitaxial layer 14. Also, a metal layer (not shown) is formed and patterned on the insulating interlayer 17, thereby forming a metal line 23. By repetition of the above process of the insulating interlayer 17 and the metal line 23, it is possible to form the necessary metal lines 23.

To protect the device from external moisture and impact, a first insulating layer 19 of oxide is formed on the insulating interlayer 17, and a second insulating layer 20 of nitride is formed on the first insulating layer 19. Subsequently, a microlens pattern 22 is formed on the second insulating layer 20 corresponding to each photodiode.

The second insulating layer 20, which functions as a passivation layer, is formed of nitride, and the microlens pattern 22 is formed of photoresist. The nitride has a poor adherence to the photoresist, whereby the second insulating layer 20 has a poor adherence to the microlens pattern 22. Accordingly, it may generate the lifting effect of the microlens pattern 22, thereby lowering the yield.

The method for manufacturing the CMOS image sensor according to the related art has at least the following disadvantages.

The second insulating layer which functions as the passivation layer is formed of nitride, and the microlens pattern is formed of the photoresist. The nitride has a poor adherence to the photoresist, whereby the second insulating layer has a poor adherence to the microlens pattern. Accordingly, it may generate the lifting effect of the microlens pattern, thereby lowering the yield.

Furthermore, the microlenses are formed at fixed intervals, which are easily separated from the second insulating layer of nitride. Due to the lifting effect of the microlenses, the microlenses become moving particles, thereby causing defective pixels and lowering the yield.

In addition, if the metal line is positioned on the path of light, it generates the diffused reflection of light, thereby deteriorating the picture quality of the CMOS image sensor.

### SUMMARY OF THE INVENTION

Accordingly, the present invention is directed to a CMOS image sensor and a method for manufacturing the same that substantially obviates one or more problems due to limitations and disadvantages of the related art.

The present invention provides a CMOS image sensor and a method for manufacturing the same, wherein an over-coating layer, which has properties similar to the photoresist of a microlens pattern, is formed on a nitride layer of a passivation layer to improve the adhesion to the microlens, to improve the flatness of surface, and to prevent external defective sources.

Additional advantages and features of the invention will be set forth in the description which follows and will become apparent to those having ordinary skill in the art upon examination of the following. These and other advantages of the invention may be realized and attained by the structure particularly pointed out in the written description and claims hereof as well as the appended drawings.

To achieve these and other advantages and in accordance with the invention, as embodied and broadly described herein, a CMOS image sensor includes a plurality of photodiodes in a semiconductor substrate; an insulating interlayer on the semiconductor substrate including the plurality of photodiodes; a metal line in the insulating interlayer; a passivation layer on the insulating interlayer; an adhesive layer on the passivation layer; and a plurality of microlenses on the adhesive layer.

The adhesive layer can be formed of an overcoating layer or an oxide layer.

Also, the overcoating layer can be very similar in properties to the microlenses.

In another aspect of the present invention, a method for manufacturing a CMOS image sensor includes forming a plurality of photodiodes in a semiconductor substrate; forming an insulating interlayer on the semiconductor substrate including the plurality of photodiodes; forming a metal line in the insulating interlayer; forming a passivation layer on the insulating interlayer; forming an adhesive layer on the passivation layer; and forming a plurality of microlenses on the adhesive layer.

The adhesive layer can be formed of a material layer which is similar in properties to photoresist of the microlenses.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention, illustrate exemplary embodiments of the invention and together with the description serve to explain the principle of the invention. In the drawings:

FIG. 1 is a cross sectional view of showing a CMOS image sensor according to the related art; and

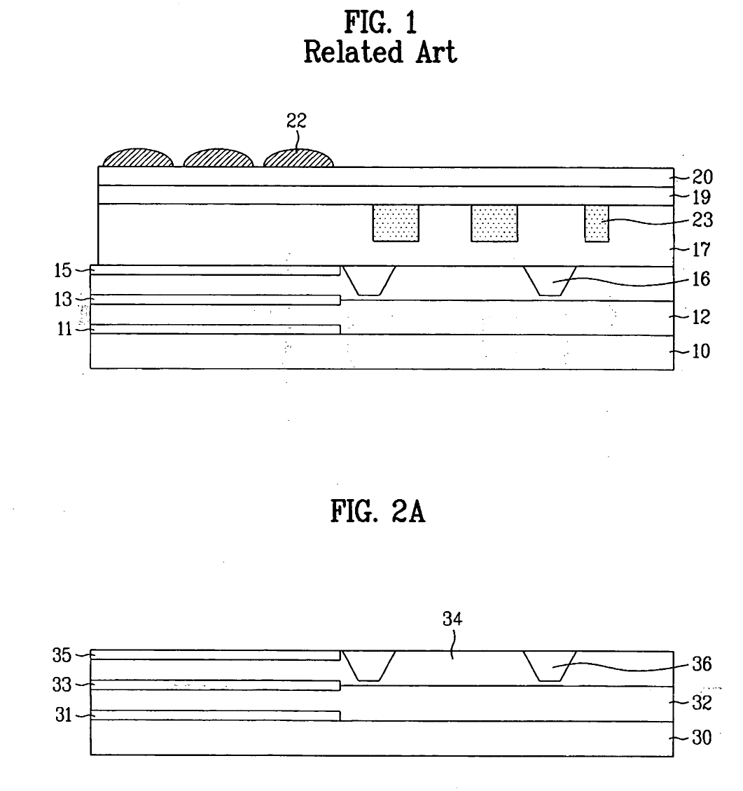

FIGS. 2A to 2C are cross sectional views of a CMOS image sensor manufactured in accordance with an exemplary embodiment according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a CMOS image sensor and a method for manufacturing the same according to the present invention will be described with reference to the accompanying drawings.

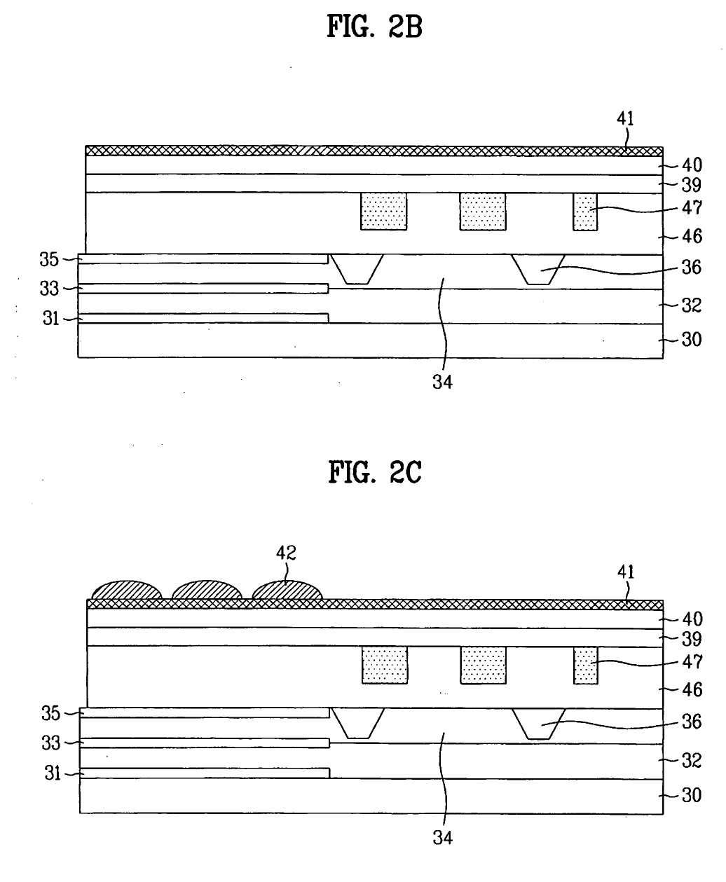

FIGS. 2A to 2C are cross sectional views of showing an exemplary method for manufacturing a CMOS image sensor according to the present invention.

As shown in FIG. 2A, a first epitaxial layer (not shown) is grown on a semiconductor substrate 30. Then, a red photodiode 31 is formed on the semiconductor substrate 30, and a second epitaxial layer 32 is grown on the semiconductor substrate 30, including the red photodiode 31. After that, a green photodiode 33 is formed in the second epitaxial layer 32. Then, a third epitaxial layer 34 is grown on the second epitaxial layer 32, including the green photodiode 33, and a blue photodiode 35 is formed in the third epitaxial layer 34. Subsequently, a trench for the isolation of fields is formed by selectively etching the semiconductor substrate 30, and the trench is filled with an insulating material to form a shallow trench isolation (STI) 36.

Referring to FIG. 2B, an insulating interlayer 46 is deposited on the third epitaxial layer 34. Then, a metal layer (not shown) is formed and patterned on the insulating interlayer 46, thereby forming a metal line 47. By repetition of the above process for forming the insulating interlayer 46 and the metal line 47, it is possible to deposit the necessary metal lines 47.

To protect the device from external moisture and impact, a first insulating layer 39 of oxide is formed on the insulating interlayer 46. Then, a second insulating layer 40 of nitride is formed on the first insulating layer 39, and an adhesive layer 41 is formed on the second insulating layer 40 to improve the adherence to microlenses.

The adhesive layer 41 is formed with an overcoating layer that has similar properties as the photoresist of the microlenses. However, the adhesive layer 41 may be formed of an oxide which has a good adhesion to the photoresist of the microlenses.

As shown in FIG. 2C, the photoresist for the microlens (not shown) is formed on the adhesive layer 41, and is then selectively removed by exposure and development to form a microlens pattern (not shown). Then, a heat treatment is applied to the microlens pattern, thereby forming the microlenses 42.

As the adhesive layer 41 is formed on the second insulating layer 41 of nitride, it is possible to improve the adhesion between the second insulating layer 40 and the adhesive layer 41 and to increase the flatness of the surface. Also, the adhesive layer 41 prevents external defective sources. In addition, it is possible to control the focal distance to the photodiode by adjusting the thickness of the adhesive layer 41.

As mentioned above, the CMOS image sensor and the method for manufacturing the same according to the present invention have at least the following advantages.

The adhesive layer is formed between the microlens and the nitride layer of the passivation layer so that it is possible to prevent the lifting effect of the microlenses. Accordingly, the yield is improved with the prevention of defective pixels, and the flatness of surface improves. In addition, it is possible to control the focal distance to the photodiode by adjusting the thickness of the adhesive layer.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A CMOS image sensor comprising:
a plurality of photodiodes in a semiconductor substrate;
an insulating interlayer on the semiconductor substrate, including the plurality of photodiodes;
a metal line in the insulating interlayer;
a passivation layer on the insulating interlayer;
an adhesive layer on the passivation layer; and
a plurality of microlenses on the adhesive layer.

2. The CMOS image sensor of claim 1, wherein the adhesive layer is formed with an overcoating layer which is similar in properties to the microlenses.

3. The CMOS image sensor of claim 1, wherein the adhesive layer is formed with an oxide layer.

4. The CMOS image sensor of claim 1, wherein the passivation layer includes an oxide layer formed on the insulating interlayer and a nitride layer formed on the oxide layer.

5. A method for manufacturing a CMOS image sensor comprising:
forming a plurality of photodiodes in a semiconductor substrate;
forming an insulating interlayer on the semiconductor substrate, including the plurality of photodiodes;
forming a metal line in the insulating interlayer;
forming a passivation layer on the insulating interlayer;
forming an adhesive layer on the passivation layer; and
forming a plurality of microlenses on the adhesive layer.

6. The method of claim 5, wherein the adhesive layer is formed with an overcoating layer which is similar in properties to the microlenses.

7. The method of claim 5, wherein the adhesive layer is formed with an oxide layer.

8. The method of claim 5, wherein the process of forming the passivation layer includes the steps of forming an oxide layer on the insulating interlayer, and forming a nitride layer on the oxide layer.
